(19) United States
(12) Patent Application Publication
(10) Pub. No.: US 2026/0100494 A1
(43) Pub. Date: Apr. 9, 2026

(54) COUPLER CIRCUIT AND WIRELESS COMMUNICATION DEVICE INCLUDING SAME

(71) Applicant: Samsung Electronics Co., Ltd., Suwon-si (KR)

(72) Inventors: Kyunghwan Kim, Suwon-si (KR); GeonHo Park, Suwon-si (KR); Byeongtaek Moon, Suwon-si (KR); Hyunchul Park, Suwon-si (KR); Sangmin Yoo, Suwon-si (KR); Joonhoi Hur, Suwon-si (KR)

(73) Assignee: Samsung Electronics Co., Ltd., Suwon-si (KR)

(21) Appl. No.: 19/224,153

(22) Filed: May 30, 2025

(30) Foreign Application Priority Data
Oct. 8, 2024 (KR) 10-2024-0136317

(51) Int. Cl. H01P 5/12; H04B 1/40

(52) U.S. Cl. CPC H01P 5/12; H04B 1/40

(57) ABSTRACT

Disclosed is a coupler circuit including a first transformer connected between a first input terminal and a first output terminal, a first inductor connected to a first node between the first input terminal and the first transformer, a first resistor connected to the first inductor, a first capacitor connected to the opposite ends of the first coil, a second capacitor connected to the opposite ends of the second coil, a second transformer connected between a second output terminal and a second node between the first inductor and the first resistor, the second transformer comprising a third foil and a fourth coil each comprising opposite ends, a third capacitor connected to the opposite ends of the third coil, a fourth capacitor connected to the opposite ends of the fourth coil, and a second inductor connected between the first output terminal and the second output terminal.

### CROSS-REFERENCE TO RELATED APPLICATIONS

This present application claims priority to and the benefit under 35 U.S.C. § 119 (a)-(d) of Korean Patent Application No. 10-2024-0136317, filed on Oct. 8, 2024, in the Korean Intellectual Property Office, the entire disclosure of which is incorporated herein by reference.

### BACKGROUND

Embodiments of the present disclosure described herein relate to a coupler circuit and a wireless communication device including the same.

As mobile communication technologies develop, there is widely supplied a wireless communication device, which is equipped with an antenna, such as a smartphone or a wearable device.

The wireless communication device may transmit and/or receive various kinds of data (e.g., a message, a photo, a video, a music file, and/or a game) through the antenna. To this end, the wireless communication device may include various circuit configurations that perform functions such as modulation/demodulation, amplification, and noise removal for radio frequency (RF) signals transmitted and received through an antenna.

The wireless communication device may include a coupler circuit that generates an orthogonal I/Q signal from a single-phase input signal. Here, to minimize the increase in area due to a transmission line included in the coupler circuit, a method of replacing the transmission line with a pi-shaped model consisting of a capacitor and an inductor is utilized.

Moreover, the wireless communication device may include a transformer that performs impedance matching between an input terminal and an output terminal to improve the gain of wireless communication.

### SUMMARY

Embodiments of the present disclosure provide a coupler circuit configured to output complex signals, having a target impedance, from an input signal having an input impedance.

According to an embodiment, a coupler circuit includes a first input terminal configured to receive an input signal having an input impedance, a first output terminal configured to output a first output signal having a target impedance, a first transformer connected between the first input terminal and the first output terminal, the first transformer comprising a first coil and a second coil, each of the first coil and the second coil comprising opposite ends, a first node between the first input terminal and the first transformer, a first inductor connected to the first node, a first resistor connected to the first inductor, a first capacitor connected in parallel to the opposite ends of the first coil of the first transformer, a second capacitor connected in parallel to the opposite ends of the second coil of the first transformer, a second output terminal configured to output a second output signal having the target impedance; a second node between the first inductor and the first resistor; a second transformer connected between the second output terminal and the second node, the second transformer comprising a third foil and a fourth coil, each of the third coil and the fourth coil comprising opposite ends, a third capacitor connected in parallel to the opposite ends of the third coil of the second transformer, a fourth capacitor connected in parallel to the opposite ends of the fourth coil of the second transformer, and a second inductor connected between the first output terminal and the second output terminal.

According to an embodiment, a wireless communication device includes an antenna configured to transmit and receive an RF signal having a predetermined frequency, a radio frequency front end (RFFE) including a coupler circuit connected to the antenna and including at least two or more transformers, and a radio frequency integrated circuit (RFIC) connected to the RFFE and configured to control a frequency of the RF signal. The coupler circuit is configured to receive a first input signal, having an input impedance, from the RFIC and output a first output signal and a second output signal, each having a target impedance and being orthogonal to each other, from the first input signal.

According to an embodiment, a coupler circuit includes a first input terminal configured to receive an input signal having an input impedance, a first output terminal configured to output a first output signal having a target impedance, a first reference node, wherein the input signal is defined with respect to the first reference node, a second reference node, wherein the first output signal is defined with respect to the second reference node, a first transformer connected between the first input terminal and the first output terminal, the first transformer comprising a first coil connected between the first input terminal and the first reference node and a second coil inductively coupled to the first coil and connected between the first output terminal and the second reference node, a first node between the first input terminal and the first coil of the first transformer, a first inductor connected to the first node, a first resistor connected to the first inductor, a second output terminal configured to output a second output signal having the target impedance, a second node between the first inductor and the first resistor, a third reference node, a fourth reference node, wherein the second output signal is defined with respect to the fourth reference node, a second transformer connected between the second output terminal and the second node, the second transformer comprising a third coil connected between the second node and the third reference node and a fourth coil connected between the second output terminal and the fourth reference node, and a second inductor connected between the first output terminal and the second output terminal.

According to an embodiment, a method of manufacturing a coupler circuit includes forming a first input terminal, forming a first output terminal, connecting a first transformer between the first input terminal and the first output terminal, the first transformer comprising a first coil and a second coil, each of the first coil and the second coil comprising opposite ends, forming a first node between the first input terminal and the first transformer, connecting a first inductor to the first node, connecting a first resistor to the first inductor, connecting a first capacitor in parallel to the opposite ends of the first coil of the first transformer, connecting a second capacitor in parallel to the opposite ends of the second coil of the first transformer, forming a second output terminal; forming a second node between the first inductor and the first resistor; connecting a second transformer between the second output terminal and the second node, the second transformer comprising a third foil and a fourth coil, each of the third coil and the fourth coil comprising opposite ends, connecting a third capacitor in parallel to the opposite ends of the third coil of the second transformer, connecting a fourth capacitor in parallel to the opposite ends of the fourth coil of the second transformer, and connecting a second inductor between the first output terminal and the second output terminal.

### BRIEF DESCRIPTION OF THE DRAWINGS

The above and other objects and features of the present disclosure will become apparent by describing in detail embodiments thereof with reference to the accompanying drawings.

FIG. 1A is a block diagram illustrating a wireless communication device, according to an embodiment of the present disclosure.

FIG. 1B is a block diagram illustrating a wireless communication device, according to another embodiment.

FIG. 2 is a block diagram showing a coupler circuit and input/output terminals of a coupler circuit, according to an embodiment.

FIG. 3 is a circuit diagram showing a coupler circuit, according to an embodiment.

FIGS. 4A to 4D are circuit diagrams showing an equivalent circuit of the coupler circuit of FIG. 3, according to an embodiment.

FIGS. 5A to 5D are circuit diagrams showing an equivalent circuit of the coupler circuit of FIG. 3, according to another embodiment.

FIG. 6 is a circuit diagram showing a coupler circuit that outputs a plurality of orthogonal signals from a differential input signal, according to an embodiment.

FIG. 7 is a circuit diagram showing a coupler circuit connected to at least one transistor, according to an embodiment.

FIG. 8 is a block diagram illustrating an electronic device, according to an embodiment.

FIG. 9 is a block diagram illustrating an IoT device including an electronic device, according to an embodiment.

FIG. 10 is a block diagram showing a mobile terminal, to which an electronic device is applied, according to an embodiment.

### DETAILED DESCRIPTION

Hereinafter, embodiments of the present disclosure will be described in detail and clearly to such an extent that an ordinary one in the art easily implements the present disclosure.

In the present disclosure, expressions such as “first,” “second,” and the like may refer to various components regardless of order and/or importance, and are only used to distinguish one component from another and do not limit the order or importance of the components.

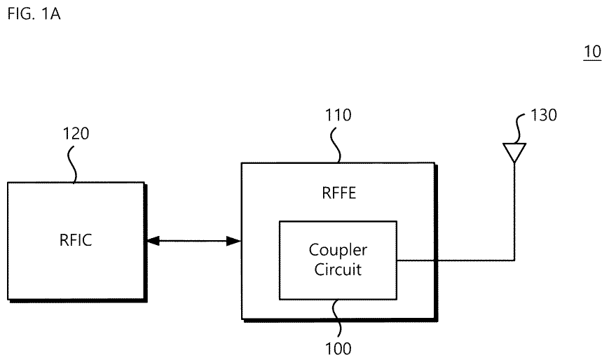

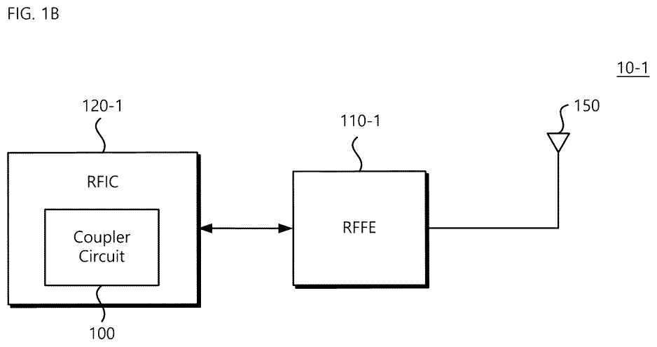

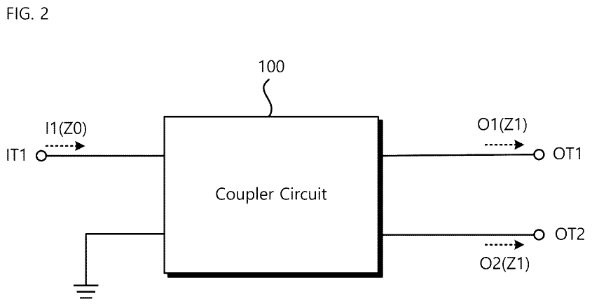

FIG. 1A is a block diagram illustrating a wireless communication device, according to an embodiment of the present disclosure. FIG. 1B is a block diagram illustrating a wireless communication device, according to another embodiment. FIG. 2 is a block diagram showing a coupler circuit and input/output terminals of a coupler circuit, according to an embodiment.

Referring to FIG. 1A, a wireless communication device 10 according to an embodiment may include a radio frequency front end (RFFE) 110, a radio frequency integrated circuit (RFIC) 120, and an antenna 130.

The wireless communication device 10 according to various embodiments of the present disclosure may be referred to as various types of devices. The wireless communication device 10 may include, for example, a portable communication device (e.g., a smartphone), a computer device, a portable multimedia device, a mobile medical appliance, a camera, or a wearable device. However, the wireless communication device 10 may not be limited to the above-described devices.

The wireless communication device 10 may include the antenna 130 configured to transmit and receive a radio frequency (RF) signal having a predetermined frequency. Accordingly, the wireless communication device 10 according to an embodiment of the present disclosure may also be referred to as a “wireless transceiver” or an “antenna device” including the antenna 130.

The wireless communication device 10 may include the RFIC 120 configured to transmit an RF signal to the antenna 130.

According to an embodiment, the RFIC 120 may be configured to control the frequency of the RF signal. In more detail, the RFIC 120 may convert a baseband signal into an RF signal, or may convert an RF signal into a baseband signal.

For example, during reception, the RFIC 120 may convert an RF signal received through the antenna 130 into a baseband signal.

Furthermore, for example, during transmission, the RFIC 120 may convert a baseband signal to an RF signal of about 700 MHz to about 3 GHz used in a first network (e.g., a legacy network).

For another example, during transmission, the RFIC 120 may convert a baseband signal into an RF signal in a Sub-6 band (about 6 GHz or less) used in a second network (e.g., a 5G network).

For still another example, during transmission, the RFIC 120 may convert a baseband signal into an RF signal of a 5G Above-5 band (e.g., about 6 GHz to about 60 GHz) used for a third network (e.g., 5G network).

Besides, the wireless communication device 10 may include the RFFE 110 connected between the RFIC 120 and the antenna 130.

According to an embodiment, the RFFE 110 may include a coupler circuit 100. Moreover, the RFFE 110 according to an embodiment may further include at least some of a phase shifter, a band pass filter, an amplifier, and a mixer.

In more detail, the RFFE 110 may include the coupler circuit 100 connected to the antenna 130.

Referring to FIG. 1B according to another embodiment, an RFIC 120-1 may include the coupler circuit 100. Here, a wireless communication device 10-1 and a configuration thereof illustrated in FIG. 1B may be understood as an example of the wireless communication device 10 and a configuration thereof illustrated in FIG. 1A.

In more detail, the wireless communication device 10-1 may include the RFIC 120-1 connected to a RFFE 110-1. Furthermore, the RFIC 120-1 may include the coupler circuit 100 that outputs complex signals.

That is, referring to the above-described configurations, the coupler circuit 100 may be included in the RFFE 110 or the RFIC 120-1. However, for convenience of description, it is assumed that the coupler circuit 100 is included in the RFFE 110.

According to an embodiment, the coupler circuit 100 may be configured to output a plurality of complex signals (e.g., I signal and Q signal) having different phases from an input signal. Here, for example, the complex signals output from the coupler circuit 100 may be applied to a phase shifter for operation of the phase shifter.

The coupler circuit 100 according to an embodiment may be configured to output an I signal and a Q signal, which are orthogonal to each other, from a single-phase input signal.

The coupler circuit 100 according to another embodiment may be configured to output quadrature-phase signals (e.g., I+ signal, I− signal, Q+ signal, and Q− signal), whose phases are sequentially shifted by 90 degrees, from differential input signals that are differential with each other.

Referring to FIG. 2, the coupler circuit 100 may be configured to output a first output signal O1(Z1) and a second output signal O2(Z1) from a first input signal I1(Z0).

In more detail, the coupler circuit 100 may be configured to receive the first input signal I1(Z0) having the input impedance Z0 through a first input terminal IT1.

Also, the coupler circuit 100 may be configured to output the first output signal O1(Z1) and the second output signal O2(Z1) which are orthogonal to each other.

In more detail, the coupler circuit 100 may be configured to output the first output signal O1(Z1) through a first output terminal OT1. Moreover, the coupler circuit 100 may be configured to output the second output signal O2(Z1) through a second output terminal OT2.

Here, the first output signal O1(Z1) and the second output signal O2(Z1) may be orthogonal to each other. For example, the first output signal O1(Z1) may have a phase of 90 degrees, and the second output signal O2(Z1) may have a phase of 180 degrees.

Accordingly, for example, the first output signal O1(Z1) may be referred to as an “I signal”. Furthermore, the second output signal O2(Z1) may be referred to as a “Q signal”.

That is, the coupler circuit 100 may be configured to generate the first output signal O1(Z1) and the second output signal O2(Z1), which are orthogonal to each other, from the first input signal I1(Z0) having a single phase.

Referring to the above-described configurations, the coupler circuit 100 may be configured to perform an operation of generating complex signals from a single-phase input signal.

Besides, here, each of the first output signal O1(Z1) and the second output signal O2(Z1) may have the target impedance Z1.

Here, the target impedance Z1 may be referred to as “impedance” for minimizing a signal reflected as a signal is delivered to the antenna 130 through an electrical path including the coupler circuit 100.

The coupler circuit 100 according to an embodiment may be configured to output the first output signal O1(Z1) and the second output signal O2(Z1), each of which has the target impedance Z1, from the first input signal I1(Z0) having the input impedance Z0.

In more detail, the coupler circuit 100 may include at least two or more transformers. Moreover, the coupler circuit 100 may be configured to convert the impedance of the first input signal I1(Z0) by using a transformer. In this way, the coupler circuit 100 may output the first output signal O1(Z1) and the second output signal O2(Z1), each of which has the target impedance Z1.

That is, the coupler circuit 100 may be configured to perform impedance matching that allows the first output signal O1(Z1) and the second output signal O2(Z1), which are generated from the first input signal I1(Z0) having the input impedance Z0, to have the target impedance Z1.

Referring to the above-described configurations, the coupler circuit 100 may be configured to output output signals having different phases from an input signal. Furthermore, the coupler circuit 100 may be configured to perform impedance matching by using a transformer such that each output signal has the target impedance Z1.

In other words, the coupler circuit 100 may be configured to perform an operation of generating complex signals from the input signal, and an impedance matching operation of allowing each of complex signals to have a target impedance.

Accordingly, compared to a case where a configuration for generating complex signals and a configuration for performing impedance matching are separately provided, the wireless communication device 10 (or the coupler circuit 100) according to an embodiment of the present disclosure may be implemented in a relatively small area.

That is, through the above-described configurations, the coupler circuit 100 according to an embodiment of the present disclosure may reduce the area required to implement the wireless communication device 10.

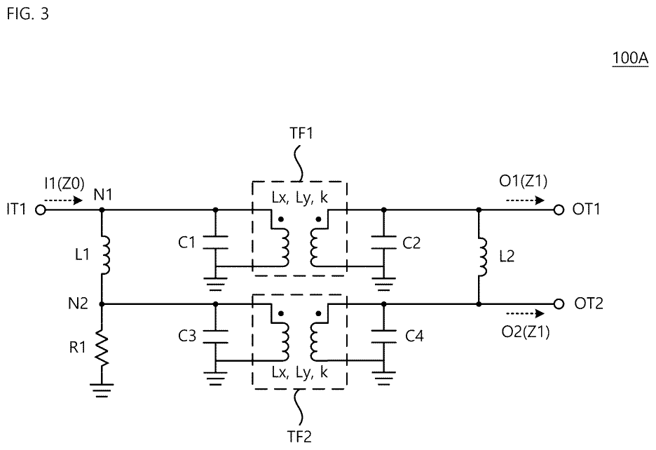

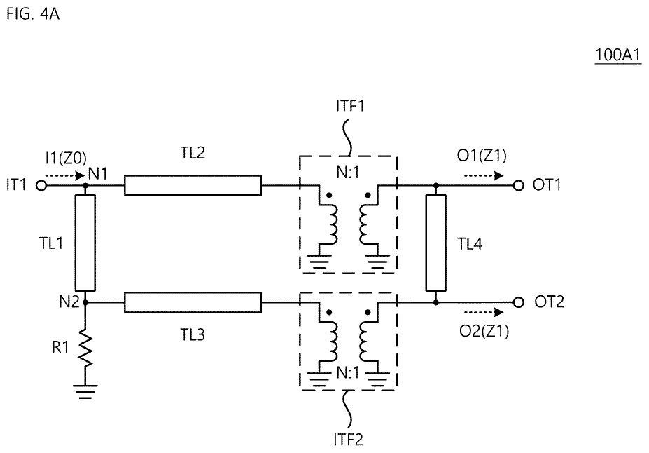

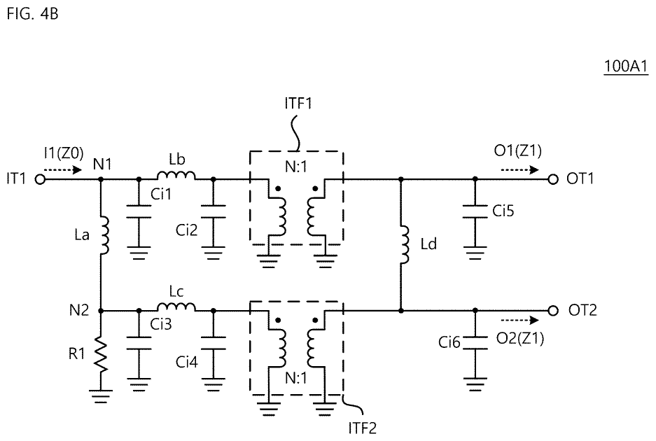

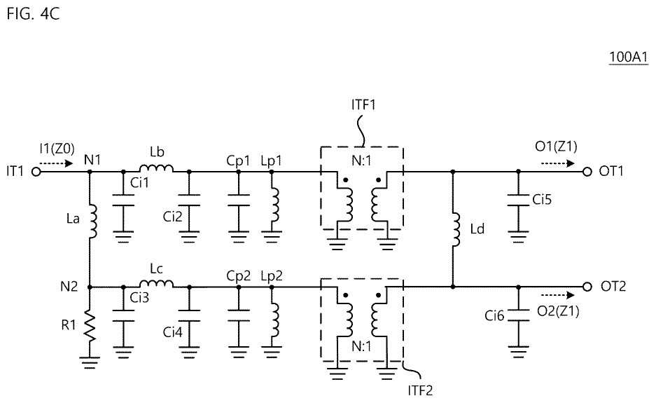

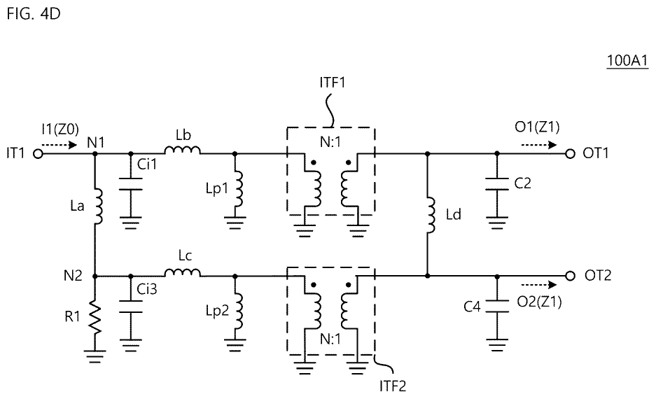

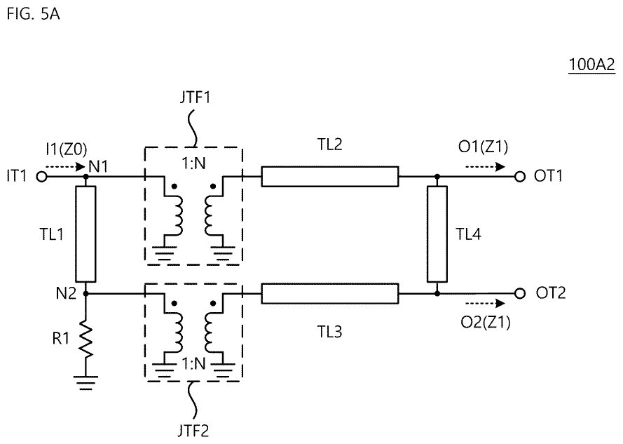

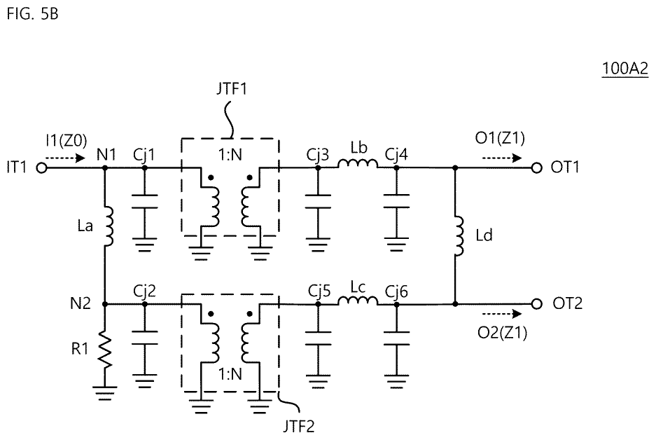

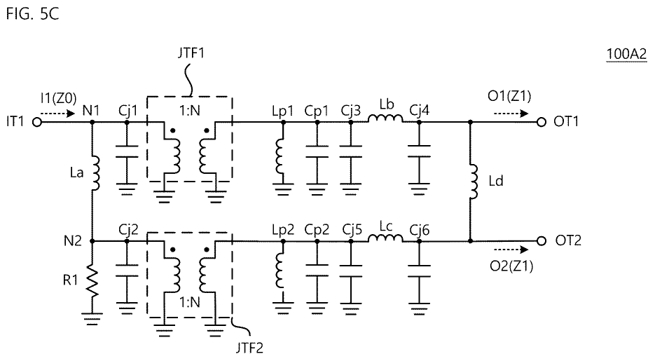

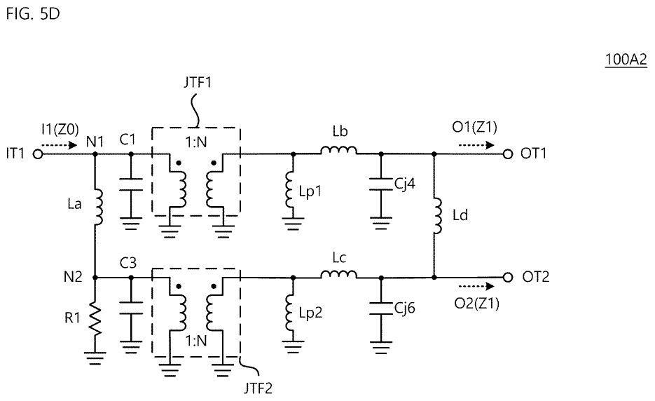

FIG. 3 is a circuit diagram showing a coupler circuit, according to an embodiment. FIGS. 4A to 4D are circuit diagrams showing an equivalent circuit of the coupler circuit of FIG. 3, according to an embodiment. FIGS. 5A to 5D are circuit diagrams showing an equivalent circuit of the coupler circuit of FIG. 3, according to another embodiment.

Referring to FIG. 3, a coupler circuit 100A according to an embodiment may include a first transformer TF1, a second transformer TF2, first to fourth capacitors C1 to C4, a first inductor L1, a second inductor L2, and a first resistor R1.

Here, the coupler circuit 100A illustrated in FIG. 3 may be referenced as an example of the coupler circuit 100 illustrated in FIGS. 1 and 2.

Referring to FIGS. 3 and 4A to 4D together, the coupler circuit 100A illustrated in FIG. 3 may be referenced as an equivalent circuit having substantially the same circuit configuration as a coupler circuit 100A1 illustrated in each of FIGS. 4A to 4D. Moreover, the circuit diagram of the coupler circuit 100A1 illustrated in each of FIGS. 4A to 4D may also be referenced as an equivalent circuit.

Referring to FIG. 4A, the coupler circuit 100A1 according to an embodiment may include a plurality of transmission lines TL1, TL2, TL3, and TL4 connecting the first input terminal IT1, the first output terminal OT1, and the second output terminal OT2.

For example, the coupler circuit 100A1 may include the second transmission line TL2 connected between the first input terminal IT1 and the first output terminal OT1. Furthermore, the coupler circuit 100A1 may include the first transmission line TL1 connected between the first input terminal IT1 and the first resistor R1. Also, the coupler circuit 100A1 may include the third transmission line TL3 connected between the second output terminal OT2 and a second node N2 between the first transmission line TL1 and the first resistor R1. Besides, the coupler circuit 100A1 may include the fourth transmission line TL4 connected between the first output terminal OT1 and the second output terminal OT2. The second node N2 may be configured as an isolated terminal of the coupler circuit 100A1.

Here, for example, each of the plurality of transmission lines TL1, TL2, TL3, and TL4 may have a length corresponding to a value obtained by dividing a wavelength according to an operating frequency ‘f’, at which the coupler circuit 100A1 operates, by 4.

In addition, the coupler circuit 100A1 may include a first ideal transformer ITF1 connected between the first output terminal OT1 and the second transmission line TL2. Moreover, the coupler circuit 100A1 may include the second ideal transformer ITF2 connected between the second output terminal OT2 and the third transmission line TL3.

The first ideal transformer ITF1 may have a first coil connected between the first input terminal IT1 and a first reference node (e.g., ground in FIGS. 3 and 4A), and the first input signal I1 may be defined with respect to the first reference node. The first ideal transformer ITF1 may have a second coil inductively coupled to the first coil and connected between the first output terminal OT1 and a second reference node (e.g., ground in FIGS. 3 and 4A), and the first output signal O1 may be defined with respect to the second reference node.

The second ideal transformer ITF2 may have a first coil (e.g., a third coil of the coupler circuit 100A) connected between the second node N2 and a third reference node (e.g., ground in FIGS. 3 and 4A). The second ideal transformer may have a second coil (e.g., a fourth coil of the coupler circuit 100A) connected between the second output terminal OT2 and a fourth reference node (e.g., ground in FIGS. 3 and 4A), and the second output signal O2 may be defined with respect to the fourth reference node.

Each of the first ideal transformer ITF1 and the second ideal transformer ITF2 may have a conversion ratio of N:1. Here, ‘N’ may have a value according to Equation 1 below.

$$N = √ ( Z 0 / Z 1 ) \qquad [ Equation 1 ]$$

Also, referring to FIGS. 4A and 4B, in a circuit diagram of the coupler circuit 100A1 according to an embodiment, each of the plurality of transmission lines TL1, TL2, TL3, and TL4 may be expressed equivalently to one inductor and two capacitors connected in a pi (π) shape.

For example, in the circuit diagram of the coupler circuit 100A1, each of the plurality of transmission lines TL1, TL2, TL3, and TL4 may be expressed equivalently to two capacitors and an inductor connected between the two capacitors.

Referring to FIG. 4B, the coupler circuit 100A1 may include a first conversion inductor La, which is one among configurations equivalent to the first transmission line TL1. The first conversion inductor La may be connected between a first node N1 and the second node N2.

The coupler circuit 100A1 may include a first intermediate capacitor Ci1 equivalent to a configuration in which one capacitor among configurations equivalent to the first transmission line TL1 and one capacitor among configurations equivalent to the second transmission line TL2 are connected in parallel. The first intermediate capacitor Ci1 may be connected between the first node N1 and a ground.

The coupler circuit 100A1 may include a second conversion inductor Lb, which is one among configurations equivalent to the second transmission line TL2. The second conversion inductor Lb may be connected between the first node N1 and the first ideal transformer ITF1.

The coupler circuit 100A1 may include a second intermediate capacitor Ci2 corresponding to one capacitor among configurations equivalent to the second transmission line TL2. The second intermediate capacitor Ci2 may be connected to ground in parallel with the first ideal transformer ITF1.

The coupler circuit 100A1 may include a third conversion inductor Lc, which is one among configurations equivalent to the third transmission line TL3. The third conversion inductor Lc may be connected between the second node N2 and the second ideal transformer ITF2.

The coupler circuit 100A1 may include a third intermediate capacitor Ci3 equivalent to a configuration in which one capacitor among configurations equivalent to the first transmission line TL1 and one capacitor among configurations equivalent to the third transmission line TL3 are connected in parallel. The third intermediate capacitor Ci3 may be connected between the second node N2 and ground.

The coupler circuit 100A1 may include a fourth intermediate capacitor Ci4 corresponding to one capacitor among configurations equivalent to the third transmission line TL3. The fourth intermediate capacitor Ci4 may be connected to ground in parallel with the second ideal transformer ITF2.

Here, the first intermediate capacitor Ci1 and the third intermediate capacitor Ci3 may have the same capacitance. Furthermore, the second intermediate capacitor Ci2 and the fourth intermediate capacitor Ci4 may have the same capacitance. In addition, the second conversion inductor Lb and the third conversion inductor Lc may have the same inductance.

Also, the coupler circuit 100A1 may include a fourth conversion inductor Ld, a fifth intermediate capacitor Ci5, and a sixth intermediate capacitor Ci6, which are equivalent to the fourth transmission line TL4. The fourth conversion inductor Ld may be connected between the first output terminal OT1 and the second output terminal OT2. Moreover, the fifth intermediate capacitor Ci5 may be connected between the first output terminal OT1 and ground. In addition, the sixth intermediate capacitor Ci6 may be connected between the second output terminal OT2 and ground.

Besides, referring to FIG. 4C, the coupler circuit 100A1 according to an embodiment may further include a first additional inductor Lp1 and a first additional capacitor Cp1, each of which is connected to ground, between the second conversion inductor Lb and the first ideal transformer ITF1.

Here, the capacitance of the first additional capacitor Cp1 may be determined by the inductance of the first additional inductor Lp1. For example, the first additional capacitor Cp1 may have capacitance according to Equation 2 below.

$$C p = \frac{1}{4 {π}^{2} {f}^{2} L p} \qquad [ Equation 2 ]$$

Here, Lp may be understood as the inductance of the first additional inductor Lp1. Furthermore, ‘f’ may be understood as the frequency at which the coupler circuit 100 operates.

Also, the coupler circuit 100A1 may include a second additional inductor Lp2 and a second additional capacitor Cp2, each of which is connected to ground, between the third conversion inductor Lc and the second ideal transformer ITF2.

Here, the first additional inductor Lp1 and the second additional inductor Lp2 may have the same inductance. Moreover, the first additional capacitor Cp1 and the second additional capacitor Cp2 may have the same capacitance.

The capacitors Ci2 and Cp1 connected between the second conversion inductor Lb and the first ideal transformer ITF1 in FIG. 4C may be included in the capacitor connected to the first output terminal OT1 in FIG. 4D.

For example, each of the first additional capacitor Cp1 and the first intermediate capacitor Ci1 of FIG. 4C may have capacitance equal to a value obtained by multiplying N² by the capacitance in a state where it is connected between the second conversion inductor Lb and the first ideal transformer ITF1, and may be expressed as a capacitor connected to the first output terminal OT1 in FIG. 4D.

That is, referring to FIG. 4D, a second capacitor C2 may have capacitance equal to a value obtained by adding a value, which is obtained by multiplying N2 by the capacitance of the capacitors Ci2 and Cp1 connected between the second conversion inductor Lb and the first ideal transformer ITF1, and the capacitance of the fifth intermediate capacitor Ci5.

Moreover, a fourth capacitor C4 may have the same capacitance as the second capacitor C2.

Furthermore, referring to FIGS. 4D and 3 together, the first ideal transformer ITF1, the second conversion inductor Lb, and the first additional inductor Lp1 may be referenced as being equivalent to the first transformer TF1. Also, the second ideal transformer ITF2, the third conversion inductor Lc, and the second additional inductor Lp2 may be referenced as being equivalent to the second transformer TF2.

The first conversion inductor La of FIG. 4D may have the same inductance as the first inductor L1 of FIG. 3. Moreover, the fourth conversion inductor Ld of FIG. 4D may have the same inductance as the second inductor L2 of FIG. 3.

The first capacitor C1 in FIG. 3 may have the same capacitance as the first intermediate capacitor Ci1 connected to the first node N1 in FIG. 4D. The third capacitor C3 in FIG. 3 may have the same capacitance as the third intermediate capacitor Ci3 connected to the second node N2 in FIG. 4D.

That is, the coupler circuit 100A illustrated in FIG. 3 may be understood as a circuit equivalent to the coupler circuit 100A1 of FIGS. 4A to 4D, which includes circuit configurations equivalent to the plurality of transmission lines TL1, TL2, TL3, and TL4 and the ideal transformers ITF1 and ITF2.

Referring to FIG. 3, the coupler circuit 100A may include the first transformer TF1 connected between the first input terminal IT1 and the first output terminal OT1.

Here, in the first transformer TF1, each of a first coil inductance Lx on one side adjacent to the first input terminal IT1, a second coil inductance Ly on the other side adjacent to the first output terminal OT1, and a coupling coefficient ‘k’ may have values based on Equations 3 to 5 below.

$$Lx = Lb + Lp \qquad [ Equation 3 ]$$

$$Ly = \frac{L p}{{N}^{2}} \qquad [ Equation 4 ]$$

$$k = \sqrt{\frac{L p}{L b + L p}} \qquad [ Equation 5 ]$$

Here, Lp may be understood as the inductance of the first additional inductor Lp1.

That is, the first transformer TF1 may be understood as a configuration derived as being equivalent to the configuration of the first ideal transformer ITF1, the second conversion inductor Lb, and the first additional inductor Lp1, which are connected to each other in FIG. 4D.

Moreover, the coupler circuit 100A may include the first inductor L1 connected to the first node N1 between the first input terminal IT1 and the first transformer TF1. Furthermore, the coupler circuit 100A may include the first resistor R1 connected between the first inductor L1 and ground.

That is, the coupler circuit 100A may include the first inductor L1 and the first resistor R1, which are connected between the first node N1 and ground in series with each other.

Here, the first inductor L1 may have inductance based on Equation 6 below.

$$L 1 = \frac{Z 0}{2 π f} \qquad [ Equation 6 ]$$

That is, the inductance of the first inductor L1 may be determined according to a value obtained by dividing the input impedance Z0 by the operating frequency ‘f’.

Also, the coupler circuit 100A may include the first capacitor C1 connected in parallel to opposite ends of the first coil of the first transformer TF1 and the second capacitor C2 connected in parallel to opposite ends of the second coil of the first transformer TF1.

In more detail, the coupler circuit 100A may include the first capacitor C1 connected to the first transformer TF1 in parallel between the first node N1 and ground. Furthermore, the coupler circuit 100A may include the second capacitor C2 connected to the first transformer TF1 in parallel between the first output terminal OT1 and ground.

Here, each of the first capacitor C1 and the second capacitor C2 may have capacitance based on Equations 7 and 8 below.

$$C 1 = \sqrt{\frac{1 + \sqrt{2}}{2 π f \times Z 0}} \qquad [ Equation 7 ]$$

$$C 2 = \frac{1}{2 π f \times Z 1} + \frac{Z 0}{Z 1} ( \frac{\sqrt{2}}{2 π f} + C p ) \qquad [ Equation 8 ]$$

Here, Cp may be understood as the capacitance of the first additional capacitor Cp1 of FIG. 4C.

Moreover, the coupler circuit 100A may include the second transformer TF2 connected between the second output terminal OT2 and the second node N2 between the first inductor L1 and the first resistor R1.

According to an embodiment, the second transformer TF2 may have the same coil inductance Lx and Ly and a coupling coefficient ‘k’ as the first transformer TF1.

Besides, the coupler circuit 100A may include the third capacitor C3 connected in parallel to opposite ends of the first coil of the second transformer (e.g., the third coil of the coupler circuit 100A) and the fourth capacitor C4 connected in parallel to opposite ends of the second coil of the second transformer TF2 (e.g., the fourth coil of the coupler circuit 100A).

In more detail, the coupler circuit 100A may include the third capacitor C3 connected to the second transformer TF2 in parallel between the second node N2 and ground. Moreover, the coupler circuit 100A may include the fourth capacitor C4 connected to the second transformer TF2 in parallel between the second output terminal OT2 and ground.

Here, the third capacitor C3 may have the same capacitance as the first capacitor C1. Furthermore, the fourth capacitor C4 may have the same capacitance as the second capacitor C2.

Also, the coupler circuit 100A may include the second inductor L2 connected between the first output terminal OT1 and the second output terminal OT2.

Here, the second inductor L2 may have inductance based on Equation 9 below.

$$L 2 = Z 1 / 2 π f \qquad [ Equation 9 ]$$

That is, the inductance of the second inductor L2 may be determined according to a value obtained by dividing the target impedance Z1 by the operating frequency ‘f’.

According to an embodiment, the coupler circuit 100A may be configured to convert the impedance of the first input signal I1(Z0) by using the first transformer TF1. For example, the coupler circuit 100A may be configured to convert the input impedance Z0 of the first input signal I1(Z0) to the target impedance Z1 by using the first transformer TF1.

In this way, the coupler circuit 100A may be configured to output the first output signal O1(Z1) having the target impedance Z1 through the first output terminal OT1.

Besides, the coupler circuit 100A may be configured to convert the impedance of a signal applied to the second node N2 by using the second transformer TF2. For example, the coupler circuit 100A may be configured to convert the input impedance Z0 of the signal applied to the second node N2 to the target impedance Z1 by using the second transformer TF2.

In this way, the coupler circuit 100A may be configured tot output the second output signal O2(Z1) having the target impedance Z1 through the second output terminal OT2.

Here, the second output signal O2(Z1) may be orthogonal to the first output signal O1(Z1). For example, the first output signal O1(Z1) may have a phase of 90 degrees, and the second output signal O2(Z1) may have a phase of 180 degrees.

Referring to the above-described configurations, the coupler circuit 100A may include the transformers TF1 and TF2 implemented by combining at least some of configurations included in equivalent circuits of the plurality of transmission lines TL1, TL2, TL3, and TL4 with the ideal transformers ITF1 and ITF2.

In more detail, the coupler circuit 100A may include the transformers TF1 and TF2 implemented by combining at least some (e.g., the second conversion inductor Lb) of inductors included in the equivalent circuits of the plurality of transmission lines TL1, TL2, TL3, and TL4 with the ideal transformers ITF1 and ITF2.

For example, the coupler circuit 100A may include the first transformer TF1 formed by combining the second conversion inductor Lb, the first additional inductor Lp1, and the first ideal transformer ITF1, which are included in the equivalent circuit of the second transmission line TL2.

The coupler circuit 100A may output the output signals O1(Z1) and O2(Z1) having different phases from the first input signal I1(Z0) by using the transformers TF1 and TF2 and a plurality of elements. Moreover, the coupler circuit 100A may be configured to perform impedance matching by using the transformers TF1 and TF2 and the plurality of elements such that each of the output signals O1(Z1) and O2(Z1) has the target impedance Z1.

That is, the coupler circuit 100A may be configured to perform an operation of generating the output signals O1(Z1) and O2(Z1) having different phases from the first input signal I1(Z0), and an impedance matching operation of allowing each of the output signals O1(Z1) and O2(Z1) to have the target impedance Z1.

Accordingly, compared to a case where a configuration for generating complex signals and a configuration for performing impedance matching are separately provided, the coupler circuit 100A according to an embodiment of the present disclosure may be implemented in a relatively small area.

That is, through the above-described configurations, the coupler circuit 100A according to an embodiment of the present disclosure may reduce the area required to implement the wireless communication device 10.

FIGS. 5A to 5D are circuit diagrams showing an equivalent circuit of the coupler circuit of FIG. 3, according to another embodiment.

Moreover, referring to FIGS. 3 and 5A to 5D together, the circuit diagram of the coupler circuit 100A illustrated in FIG. 3 may be referenced as an equivalent circuit having substantially the same configuration as the circuit diagram of a coupler circuit 100A2 illustrated in each of FIGS. 5A to 5D.

Moreover, the circuit diagram of the coupler circuit 100A2 illustrated in each of FIGS. 5A to 5D may also be referenced as an equivalent circuit.

However, it may be understood that the configuration of at least some of the coupler circuit 100A2 illustrated in FIGS. 5A to 5D is substantially the same as a portion of the configuration of the coupler circuit 100A1 illustrated in FIGS. 4A to 4D.

Accordingly, the same reference numerals are used for components the same or substantially the same as the above-described components, and descriptions the same as the above-described descriptions are omitted to avoid redundancy.

Referring to FIG. 5A, the coupler circuit 100A2 according to an embodiment may include a plurality of transmission lines TL1, TL2, TL3, and TL4 connecting the first input terminal IT1, the first output terminal OT1, and the second output terminal OT2.

Moreover, the coupler circuit 100A2 may include a first ideal transformer JTF1 connected between the first input terminal IT1 and the second transmission line TL2. Furthermore, the coupler circuit 100A2 may include a second ideal transformer JTF2 connected between the second node N2 and the third transmission line TL3.

Each of the first ideal transformer JTF1 and the second ideal transformer JTF2 may have a conversion ratio of 1:N.

Also, referring to FIGS. 5A and 5B, in a circuit diagram of the coupler circuit 100A2 according to an embodiment, each of the plurality of transmission lines TL1, TL2, TL3, and TL4 may be expressed equivalently to one inductor and two capacitors connected in a pi (π) shape.

Referring to FIG. 5B, the coupler circuit 100A2 may include a first conversion inductor La, which is one among configurations equivalent to the first transmission line TL1. The first conversion inductor La may be connected between the first node N1 and the second node N2.

The coupler circuit 100A2 may include a first intermediate capacitor Cj1 corresponding to one capacitor among configurations equivalent to the first transmission line TL1. The first intermediate capacitor Cj1 may be connected between the first node N1 and a ground.

The coupler circuit 100A2 may include a second intermediate capacitor Cj2 corresponding to one capacitor among configurations equivalent to the first transmission line TL1. The second intermediate capacitor Cj2 may be connected between the second node N2 and ground.

Here, the first intermediate capacitor Cj1 and the second intermediate capacitor Cj2 may have the same capacitance.

The coupler circuit 100A2 may include a second conversion inductor Lb, which is one among configurations equivalent to the second transmission line TL2. The second conversion inductor Lb may be connected between the first ideal transformer JTF1 and the first output terminal OT1.

The coupler circuit 100A2 may include a third intermediate capacitor Cj3 corresponding to one capacitor among configurations equivalent to the second transmission line TL2. The third intermediate capacitor Cj3 may be connected to ground in parallel with the first ideal transformer JTF1.

The coupler circuit 100A2 may include a fourth intermediate capacitor Cj4 equivalent to a configuration in which one capacitor among configurations equivalent to the second transmission line TL2 and one capacitor among configurations equivalent to the fourth transmission line TL4 are connected in parallel. The fourth intermediate capacitor Cj4 may be connected between the first output terminal OT1 and ground.

The coupler circuit 100A2 may include a third conversion inductor Lc, which is one among configurations equivalent to the third transmission line TL3. The third conversion inductor Lc may be connected between the second ideal transformer JTF2 and the second output terminal OT2.

The coupler circuit 100A2 may include a fifth intermediate capacitor Cj5 corresponding to one capacitor among configurations equivalent to the third transmission line TL3. The fifth intermediate capacitor Cj5 may be connected to ground in parallel with the second ideal transformer JTF2.

The coupler circuit 100A2 may include a sixth intermediate capacitor Cj6 equivalent to a configuration in which one capacitor among configurations equivalent to the third transmission line TL3 and one capacitor among configurations equivalent to the fourth transmission line TL4 are connected in parallel. The sixth intermediate capacitor Cj6 may be connected between the second output terminal OT2 and ground.

Furthermore, the third intermediate capacitor Cj3 and the fifth intermediate capacitor Cj5 may have the same capacitance. Furthermore, the fourth intermediate capacitor Cj4 and the sixth intermediate capacitor Cj6 may have the same capacitance. In addition, the second conversion inductor Lb and the third conversion inductor Lc may have the same inductance.

Moreover, the coupler circuit 100A2 may include the fourth conversion inductor Ld, which is one among configurations equivalent to the fourth transmission line TL4. The fourth conversion inductor Ld may be connected between the first output terminal OT1 and the second output terminal OT2.

Besides, referring to FIG. 5C, the coupler circuit 100A2 according to an embodiment may further include the first additional inductor Lp1 and the first additional capacitor Cp1, each of which is connected to ground, between the second conversion inductor Lb and the first ideal transformer JTF1. Here, the capacitance of the first additional capacitor Cp1 may be determined by the inductance of the first additional inductor Lp1.

Also, the coupler circuit 100A2 may include a second additional inductor Lp2 and a second additional capacitor Cp2, each of which is connected to ground, between the third conversion inductor Lc and the second ideal transformer JTF2.

Here, the first additional inductor Lp1 and the second additional inductor Lp2 may have the same inductance. Moreover, the first additional capacitor Cp1 and the second additional capacitor Cp2 may have the same capacitance.

The capacitors Cj3 and Cp1 connected between the second conversion inductor Lb and the first ideal transformer JTF1 in FIG. 5C may be included in the capacitor connected to the first input terminal IT1 (or the first node N1) in FIG. 5D.

For example, each of the first additional capacitor Cp1 and the third intermediate capacitor Cj3 of FIG. 5C may have capacitance equal to a value obtained by multiplying N2 by the capacitance in a state where it is connected between the second conversion inductor Lb and the first ideal transformer JTF1, and may be expressed as a capacitor connected to the first input terminal IT1 in FIG. 5D.

That is, the first capacitor C1 may have capacitance equal to a value obtained by adding a value, which is obtained by multiplying N2 by the capacitance of the capacitors Cj3 and Cp1 connected between the second conversion inductor Lb and the first ideal transformer JTF1, and the capacitance of the first intermediate capacitor Cj1.

Moreover, the third capacitor C3 may have the same capacitance as the first capacitor C1.

Furthermore, referring to FIGS. 5D and 3 together, the first ideal transformer JTF1, the second conversion inductor Lb, and the first additional inductor Lp1 may be referenced as being equivalent to the first transformer TF1. Also, the second ideal transformer JTF2, the third conversion inductor Lc, and the second additional inductor Lp2 may be referenced as being equivalent to the second transformer TF2.

The first conversion inductor La of FIG. 5D may have the same inductance as the first inductor L1 of FIG. 3. Moreover, the fourth conversion inductor Ld of FIG. 5D may have the same inductance as the second inductor L2 of FIG. 3.

That is, referring to FIG. 3, the coupler circuit 100A may include the transformers TF1 and TF2 implemented by combining at least some of inductors included in equivalent circuits of the plurality of transmission lines TL1, TL2, TL3, and TL4 with the ideal transformers JTF1 and JTF2.

For example, the coupler circuit 100A may include the first transformer TF1 formed by combining the second conversion inductor Lb, the first additional inductor Lp1, and the first ideal transformer JTF1, which are included in the equivalent circuit of the second transmission line TL2.

The coupler circuit 100A may be configured to output the output signals O1(Z1) and O2(Z1) having different phases from the first input signal I1(Z0) by using the transformers TF1 and TF2 and a plurality of elements.

Moreover, the coupler circuit 100A may be configured to perform impedance matching by using the transformers TF1 and TF2 and the plurality of elements such that each of the output signals O1(Z1) and O2(Z1) has the target impedance Z1.

That is, the coupler circuit 100A may be configured to perform an operation of generating the output signals O1(Z1) and O2(Z1) having different phases from the first input signal I1(Z0), and an impedance matching operation of allowing each of the output signals O1(Z1) and O2(Z1) to have the target impedance Z1.

Accordingly, compared to a case where a configuration for generating complex signals and a configuration for performing impedance matching are separately provided, the coupler circuit 100A according to an embodiment of the present disclosure may be implemented in a relatively small area.

That is, through the above-described configurations, the coupler circuit 100A according to an embodiment of the present disclosure may reduce the area required to implement the wireless communication device 10.

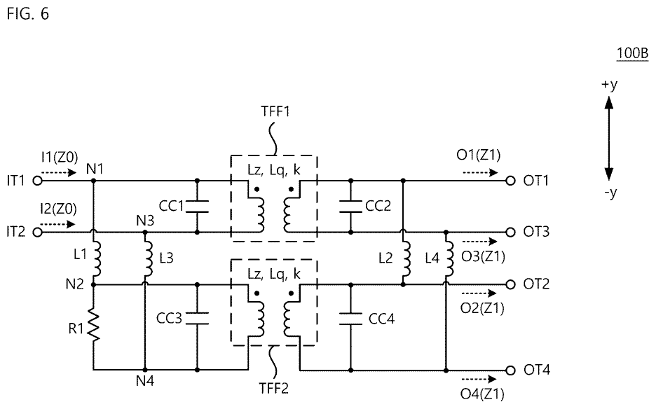

FIG. 6 is a circuit diagram showing a coupler circuit that outputs a plurality of orthogonal signals from a differential input signal, according to an embodiment.

Referring to FIG. 6, a coupler circuit 100B according to an embodiment may include a first transformer TFF1, a second transformer TFF2, first to fourth capacitors CC1 to CC4, first to fourth inductors L1 to L4, and the first resistor R1.

Here, the coupler circuit 100B illustrated in FIG. 6 may be an example of the coupler circuit 100 illustrated in FIG. 1. Accordingly, the same reference numerals are used for components the same or substantially the same as the above-described components, and descriptions the same as the above-described descriptions are omitted to avoid redundancy.

Referring to FIG. 6, the coupler circuit 100B may include the first transformer TFF1 connected between the first and second input terminals IT1 and IT2, and the first and third output terminals OT1 and OT3.

Here, a first coil inductance Lz on one side adjacent to the first input terminal IT1 and the second input terminal IT2 of the first transformer TFF1, and a second coil inductance Lq on the other side adjacent to the first output terminal OT1 and the third output terminal OT3 may have values based on Equations 10 and 11, respectively.

$$Lz = 2 ( L b + Lp ) \qquad [ Equation 10 ]$$

$$Lq = 2 \times \frac{L p}{{N}^{2}} \qquad [ Equation 11 ]$$

Furthermore, the coupling coefficient ‘k’ of the first transformer TFF1 illustrated in FIG. 6 may have a value based on Equation 5 described above.

Moreover, the coupler circuit 100B may include the first inductor L1 connected to the first node N1 between the first input terminal IT1 and the first transformer TFF1. In more detail, the coupler circuit 100B may include the first inductor L1 connected between the first node N1 and the second node N2. Here, the first inductor L1 may have inductance based on Equation 6 described above.

Furthermore, the coupler circuit 100B may include the first resistor R1 connected to the first inductor L1. In more detail, the coupler circuit 100B may include the first resistor R1, which is connected to the first inductor L1 via the second node N2.

The coupler circuit 100B may include the first capacitor CC1 connected in parallel to opposite ends of the first coil of the first transformer TFF1 and the second capacitor CC2 connected in parallel to opposite ends of the second coil of the first transformer TFF1.

In more detail, the coupler circuit 100B may include the first capacitor CC1 connected to the first transformer TFF1 in parallel between the first input terminal IT1 and the second input terminal IT2. In addition, the coupler circuit 100B may include the second capacitor CC2 connected to the first transformer TFF1 in parallel between the first output terminal OT1 and the third output terminal OT3.

Here, the first capacitor CC1 may have capacitance based on Equation 12 below.

$$C C 1 = \frac{\sqrt{\frac{1 + \sqrt{2}}{2 π f \times Z 0}}}{2} \qquad [ Equation 12 ]$$

Moreover, the second capacitor CC2 may have capacitance based on Equation 13 below.

$$CC 2 = \frac{\frac{1}{2 π f \times Z 1} + \frac{Z 0}{Z 1} ( \frac{\sqrt{2}}{2 π f} + C p )}{2} \qquad [ Equation 13 ]$$

Here, Cp may be understood as the capacitance of an additional capacitor (e.g., the first additional capacitor Cp1 of FIG. 4C) added to the equivalent circuit of the coupler circuit 100B together with an additional inductor (e.g., the first additional inductor Lp1 of FIG. 4C).

Also, the coupler circuit 100B may include the second transformer TFF2 connected between the second and fourth output terminals OT2 and OT4 and the second node N2 between the first inductor L1 and the first resistor R1.

According to an embodiment, the second transformer TFF2 may have the same coil inductance Lz and Lq and the coupling coefficient k as the first transformer TFF1.

Besides, the coupler circuit 100B may include the third capacitor CC3 connected in parallel to opposite ends of the first coil (e.g., third coil) of the second transformer TFF2 and the fourth capacitor CC4 connected in parallel to opposite ends of the second coil (e.g., fourth coil) of the second transformer TFF2.

In more detail, the coupler circuit 100B may include the third capacitor CC3 connected in parallel with the first resistor R1 and the second transformer TFF2 at the second node N2. In more detail, the coupler circuit 100B may include the third capacitor CC3 connected in parallel with the second transformer TFF2 between the second node N2 and a fourth node N4. The fourth node N4 may be configured as differential with the second node N2 (e.g., when the second node N2 is configured as an isolated terminal).

In addition, the coupler circuit 100B may include the fourth capacitor CC4 connected to the second transformer TFF2 in parallel between the second output terminal OT2 and the fourth output terminal OT4.

Here, the third capacitor CC3 may have the same capacitance as the first capacitor CC1. Furthermore, the fourth capacitor CC4 may have the same capacitance as the second capacitor CC2.

Moreover, the coupler circuit 100B may include the third inductor L3 connected to the second input terminal IT2.

In more detail, the coupler circuit 100B may include the third inductor L3 connected between a third node N3 between the second input terminal IT2 and the first transformer TFF1, and the fourth node N4 between the first resistor R1 and the second transformer TFF2. Here, the third inductor L3 may have the same inductance as the first inductor L1.

Furthermore, the third inductor L3 may be adjacent to the first inductor L1. For example, the third inductor L3 may be adjacent to the first inductor L1 within a predetermined distance.

Besides, the first inductor L1 and the third inductor L3 may be configured to flow currents in opposite directions to each other.

For example, the current formed in the first inductor L1 may be formed in a direction from the first node N1 to the second node N2 (e.g., −y direction). In addition, the current formed in the third inductor L3 may be formed in a direction (e.g., +y direction) from the fourth node N4 toward the third node N3.

In this way, the third inductor L3 and the first inductor L1 may be inductively coupled to each other.

Through the above-described configurations, the first inductor L1 and the third inductor L3 may be implemented to have relatively low inductance compared to a case where they are not coupled to each other.

Also, the coupler circuit 100B may include the second inductor L2 connected between the first output terminal OT1 and the second output terminal OT2. Here, the second inductor L2 may have inductance based on Equation 9 described above.

Moreover, the coupler circuit 100B may include the fourth inductor L4 connected between the third output terminal OT3 and the fourth output terminal OT4. Here, the fourth inductor L4 may have the same inductance as the second inductor L2.

Moreover, the fourth inductor L4 may be adjacent to the second inductor L2. For example, the fourth inductor L4 may be adjacent to the second inductor L2 within a predetermined distance.

Besides, the second inductor L2 and the fourth inductor L4 may be configured to flow currents in opposite directions to each other.

For example, the current formed in the second inductor L2 may be formed in a direction (e.g., −y direction) from the first output terminal OT1 to the second output terminal OT2. Moreover, the current formed in the fourth inductor L4 may be formed in a direction (e.g., +y direction) from the fourth output terminal OT4 to the third output terminal OT3.

In this way, the fourth inductor L4 and the second inductor L2 may be inductively coupled to each other.

Through the above-described configurations, the second inductor L2 and the fourth inductor L4 may be implemented to have relatively low inductance compared to a case where they are not coupled to each other.

Referring to the above-described configurations, at least two or more inductors included in the coupler circuit 100B according to an embodiment may be coupled by being adjacent to each other.

In this way, the coupler circuit 100B according to an embodiment of the present disclosure may be implemented in a relatively small area.

The coupler circuit 100B according to an embodiment may be configured to output the first to fourth output signals O1(Z1) to O4(Z1), each of which has the target impedance Z1, from the first and second input signals I1(Z0) and I2(Z0) having the input impedance Z0.

The coupler circuit 100B may be configured to receive the first input signal I1(Z0) through the first input terminal IT1. Furthermore, the coupler circuit 100B may be configured to receive the second input signal I2(Z0) through the second input terminal IT2.

Here, the first input signal I1(Z0) and the second input signal I2(Z0) may be differential with each other. For example, the first input signal I1(Z0) may have a phase of 0 degrees, and the second input signal I2(Z0) may have a phase of 180 degrees.

Moreover, the coupler circuit 100B may be configured to output the first output signal O1(Z1) through the first output terminal OT1. Furthermore, the coupler circuit 100B may be configured to output the second output signal O2(Z1) through the second output terminal OT2. Also, the coupler circuit 100B may be configured to output the third output signal O3(Z1) through the third output terminal OT3. Besides, the coupler circuit 100B may be configured to output the fourth output signal O4(Z1) through the fourth output terminal OT4.

The first coil of the first ideal transformer TFF1 may be connected between the first input terminal IT1 and a first reference node (e.g., connected to the second input terminal IT2 in FIG. 6), and the first input signal I1 may be defined with respect to the first reference node. The second coil of the first ideal transformer TFF1 may be connected between the first output terminal OT1 and a second reference node (e.g., connected to the third output terminal OT3 in FIG. 6), and the first output signal O1 may be defined with respect to the second reference node.

The first coil (e.g., third coil) of the second ideal transformer TFF2 may be connected between the second node N2 and a third reference node (e.g., fourth node N4 in FIG. 6). The second coil (e.g., fourth coil) of the second ideal transformer IFF2 may be connected between the second output terminal OT2 and a fourth reference node (e.g., connected to the fourth output terminal OT4 in FIG. 6), and the second output signal O2 may be defined with respect to the fourth reference node.

Here, the first to fourth output signals O1(Z1) to O4(Z1) may be understood as complex signals whose phases are sequentially shifted by 90 degrees. For example, the first output signal O1(Z1) may have a phase of 90 degrees; the second output signal O2(Z1) may have a phase of 180 degrees; the third output signal O3(Z1) may have a phase of 270 degrees; and, the fourth output signal O4(Z1) may have a phase of 0 degrees.

Accordingly, for example, the first output signal O1(Z1) may be referred to as “Q+ signal”; the second output signal O2(Z1) may be referred to as “I+ signal”; the third output signal O3(Z1) may be referred to as “Q− signal”; and, the fourth output signal O4(Z1) may be referred to as “I− signal”.

Referring to the above-described configurations, the coupler circuit 100B may be configured to output the output signals O1(Z1) to O4(Z1) having different phases from the first input signal I1(Z0) and the second input signal I2(Z0) by using the transformers TFF1 and TFF2 and a plurality of elements.

Moreover, the coupler circuit 100B may be configured to perform impedance matching by using the transformers TFF1 and TFF2 and the plurality of elements such that each of the output signals O1(Z1) to O4(Z1) has the target impedance Z1.

That is, the coupler circuit 100B may be configured to perform an operation of generating the output signals O1(Z1) to O4(Z1) having different phases from the first input signal I1(Z0) and the second input signal I2(Z0), and an impedance matching operation of allowing each of the output signals O1(Z1) to O4(Z1) to have the target impedance Z1.

Accordingly, compared to a case where a configuration for generating complex signals and a configuration for performing impedance matching are separately provided, the coupler circuit 100B according to an embodiment of the present disclosure may be implemented in a relatively small area.

That is, through the above-described configurations, the coupler circuit 100B according to an embodiment of the present disclosure may reduce the area required to implement the wireless communication device 10.

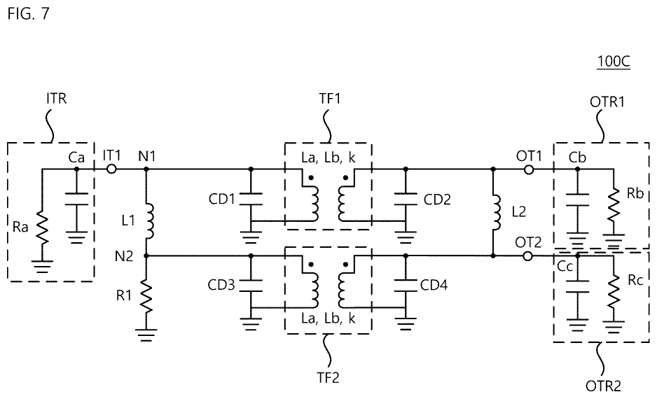

FIG. 7 is a circuit diagram showing a coupler circuit connected to at least one transistor, according to an embodiment.

Referring to FIG. 7, a coupler circuit 100C according to an embodiment may include the first transformer TF1, the second transformer TF2, first to fourth capacitors CD1 to CD4, the first inductor L1, the second inductor L2, the first resistor R1, an input transistor ITR, a first output transistor OTR1, and a second output transistor OTR2.

The coupler circuit 100C illustrated in FIG. 7 may be understood as an example of the coupler circuit 100 illustrated in FIG. 2. Moreover, the coupler circuit 100C illustrated in FIG. 7 may be understood as a configuration that further includes the input transistor ITR, the first output transistor OTR1, and the second output transistor OTR2 in the configuration of the coupler circuit 100 illustrated in FIG. 3.

Accordingly, the same reference numerals are used for components the same or substantially the same as the above-described components, and descriptions the same as the above-described descriptions are omitted to avoid redundancy.

The coupler circuit 100C may include the input transistor ITR connected to the first input terminal IT1.

The input transistor ITR may include an input resistor Ra and an input capacitor Ca connected in parallel between the first input terminal IT1 and ground. Here, the input capacitor Ca may be understood as a parasitic capacitor of the input transistor ITR.

In this case, the first capacitor CD1 may have capacitance obtained by subtracting a value corresponding to the capacitance of the input capacitor Ca from a value calculated based on Equation 7 described above.

Here, the value calculated based on Equation 7 may be referred to as “first capacitance”.

That is, when the first input terminal IT1 is connected to the input transistor ITR, the first capacitor CD1 of the coupler circuit 100C may have a first subtraction capacitance obtained by subtracting parasitic capacitance of the input transistor ITR from the first capacitance calculated from the input impedance Z0 and the operating frequency ‘f’.

Moreover, the coupler circuit 100C may include the first output transistor OTR1 connected to the first output terminal OT1.

The first output transistor OTR1 may include a first output resistor Rb and a first output capacitor Cb connected in parallel between the first output terminal OT1 and ground. Here, the first output capacitor Cb may be understood as a parasitic capacitor of the first output transistor OTR1.

In this case, the second capacitor CD2 may have capacitance obtained by subtracting the capacitance of the first output capacitor Cb from a value calculated based on Equation 8 described above.

Here, the value calculated based on Equation 8 may be referred to as “second capacitance”.

That is, when the first output terminal OT1 is connected to the first output transistor OTR1, the second capacitor CD2 of the coupler circuit 100C may have second subtraction capacitance obtained by subtracting parasitic capacitance of the first output transistor OTR1 from the second capacitance calculated from the target impedance Z1 and the operating frequency ‘f’.

Moreover, the coupler circuit 100C may include the second output transistor OTR2 connected to the second output terminal OT2.

The second output transistor OTR2 may include a second output resistor Rc and a second output capacitor Cc connected in parallel between the second output terminal OT2 and ground. Here, the second output capacitor Cc may be understood as a parasitic capacitor of the second output transistor OTR2.

In this case, the fourth capacitor CD4 may have capacitance obtained by subtracting the capacitance of the second output capacitor Cc from capacitance of the second capacitor CD2 calculated based on Equation 8 described above. That is, when the second output terminal OT2 is connected to the second output transistor OTR2, the fourth capacitor CD4 of the coupler circuit 100C may have a capacitance obtained by subtracting parasitic capacitance of the second output transistor OTR2 from the capacitance calculated from the target impedance Z1 and the operating frequency ‘f’.

However, according to another embodiment, at least some of the above-described transformers ITR, OTR1, and OTR2 may be omitted.

Referring to the above-described configurations, when a transistor is connected to at least some of the input terminal IT1 or the output terminals OT1 and OT2, the capacitance of a capacitor (e.g., the first capacitor CD1) connected to the transformers TF1 and TF2 in the coupler circuit 100C may be reduced by the parasitic capacitance of the connected transistor.

In this way, the coupler circuit 100C according to an embodiment of the present disclosure may be implemented to have a relatively small area.

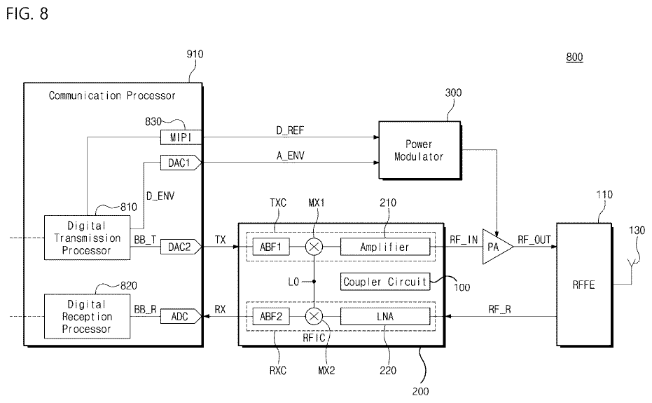

FIG. 8 is a block diagram illustrating an electronic device, according to an embodiment.

Referring to FIG. 8, a wireless communication device 800 according to an embodiment of the present disclosure may include a communication processor 910, an RFIC 200, a power modulator 300, the RFFE 110, a power amplifier PA, the antenna 130.

Here, the wireless communication device 800 illustrated in FIG. 8 may be understood as an example of the wireless communication device 10 illustrated in FIG. 1. Accordingly, the same reference numerals are used for components the same or substantially the same as the above-described components, and descriptions the same as the above-described descriptions are omitted to avoid redundancy.

The communication processor 910 may process a baseband signal BB_T through a digital transmission processor 810 in compliance with a given communication scheme. Furthermore, the communication processor 910 may process a received baseband signal BB_R through a digital reception processor 820 in compliance with the given communication scheme.

For example, the communication processor 910 may process a signal to be transmitted or a received signal in compliance with a communication scheme such as orthogonal frequency division multiplexing (OFDM), orthogonal frequency division multiplexing access (OFDMA), wideband code multiple access (WCDMA), or high speed packet access+ (HSPA+). Besides, the communication processor 910 may process the baseband signal BB_T or BB_R in compliance with various kinds of communication schemes (i.e., various communication schemes to which a technology for modulating or demodulating the amplitude and frequency of the baseband signal BB_T or BB_R is applied).

The communication processor 910 may extract envelop of the baseband signal BB_T through the digital transmission processor 810 and may generate a digital envelop signal D_ENV based on the extracted envelop. Moreover, the communication processor 910 may generate an average power signal D_REF based on an average power tracking table stored in a memory. Here, the extracted envelop may correspond to an amplitude component (i.e., a magnitude of each of I signal and Q signal) of the baseband signal BB_T.

Here, the communication processor 910 may perform digital-to-analog conversion on the baseband signal BB_T and the digital envelop signal D_ENV by using a plurality of digital-to-analog converters DAC1 and DAC2 included therein and may generate a transmit signal TX and an analog envelop signal A_ENV being analog signals. That is, the average power signal D_REF output from the communication processor 910 may be a digital signal. As such, the average power signal D_REF may be provided to a digital-to-analog converter included in the power modulator 300 through a MIPI 830 and may be converted into an analog signal, for example, the reference voltage signal through the digital-to-analog converter included in the power modulator 300. In an embodiment, the digital-to-analog converters DAC1 and DAC2 included in the communication processor 910 may operate at a speed higher than the digital-to-analog converter included in the power modulator 300.

However, the present disclosure is not limited thereto. For example, the communication processor 910 may convert the average power signal D_REF into an analog signal through a digital-to-analog converter included therein. In this case, the communication processor 910 may provide average power signal converted into the analog signal to the power modulator 300.

However, for convenience of description, in the embodiment of the present disclosure, the description will be given as the communication processor 910 provides the average power signal D_REF to the digital-to-analog converter included in the power modulator 300 through the MIPI 830.

In an embodiment, each of the transmit signal TX and the analog envelop signal A_ENV may be implemented with differential signals including a positive signal and a negative signal.

Also, the communication processor 910 may be provided with a receive signal RX being an analog signal from the RFIC 200. Moreover, the communication processor 910 may perform analog-to-digital conversion on the receive signal RX through the analog-to-digital converter ADC included therein and may extract the baseband signal BB_R being a digital signal. Here, the receive signal RX may be implemented with differential signals including a positive signal and a negative signal.

The RFIC 200 may generate an RF input signal RF_IN by performing frequency up-conversion on the transmit signal TX or may generate the receive signal RX by performing frequency down-conversion on an RF receive signal RF_R. In detail, the RFIC 200 may include a transmission circuit TXC for frequency up-conversion, a reception circuit RXC for frequency down-conversion, and a local oscillator LO.

Here, the RFIC 200 illustrated in FIG. 8 may be understood as having substantially the same configuration as the RFIC 120 illustrated in FIG. 1.

Here, the transmission circuit TXC may include a first analog baseband filter ABF1, a first mixer MX1, and an amplifier 210. For example, the first analog baseband filter ABF1 may include a low pass filter.

The first analog baseband filter ABF1 may filter the transmit signal TX received from the communication processor 910 so as to be provided to the first mixer MX1. Furthermore, the first mixer MX1 may perform frequency up-conversion for converting a frequency of the transmit signal TX from a baseband to a high-frequency band through a frequency signal provided by the local oscillator LO. The transmit signal TX may be provided to the amplifier 210 as the RF input signal RF_IN, and the amplifier 210 may first amplify a power of the RF input signal RF_IN so as to be provided to the power amplifier PA.

The power amplifier PA may be supplied with a power supply voltage (i.e., a dynamically variable output voltage) from the power modulator 300, may second amplify a power of the RF input signal RF_IN based on the supplied power supply voltage, and may generate an RF output signal RF_OUT. The power amplifier PA may provide the generated RF output signal RF_OUT thus generated to the RFFE 110.

The reception circuit RXC may include a second analog baseband filter ABF2, a second mixer MX2, and a low-noise amplifier 220. For example, the second analog baseband filter ABF2 may include a low pass filter.

The low-noise amplifier 220 may amplify the RF receive signal RF_R provided from the RFFE 110 so as to be provided to the second mixer MX2. Moreover, the second mixer MX2 may perform frequency down-conversion for converting a frequency of the RF receive signal RF_R from a high-frequency band to a baseband through a frequency signal provided by the local oscillator LO. The RF receive signal RF_R may be provided to the second analog baseband filter ABF2 as the receive signal RX through the above frequency down-conversion, and the second analog baseband filter ABF2 may filter the receive signal RX so as to be provided to the communication processor 910.

In an embodiment, the wireless communication device 800 may transmit a transmit signal through a plurality of frequency bands by using carrier aggregation (CA). Also, to this end, the wireless communication device 800 may include a plurality of power amplifiers for amplifying powers of a plurality of RF input signals RF_IN respectively corresponding to a plurality of carriers. However, in the embodiment of the present disclosure, for convenience of description, the description will be given as the number of power amplifiers PA is “1”.

Also, the RFIC 200 according to an embodiment may further include the coupler circuit 100.

In more detail, the RFIC 200 may further include the coupler circuit 100 for outputting a plurality of complex signals having different phases from an input signal. Here, the coupler circuit 100 may be understood as having substantially the same configuration as the coupler circuit 100 illustrated in FIG. 1B.

For example, the coupler circuit 100 may be configured to output an I signal and a Q signal (e.g., the first output signal O1(Z1) and the second output signal O2(Z1) of FIG. 2), which are orthogonal to each other, from a single-phase input signal (e.g., the first input signal I1(Z0) of FIG. 2).

For another example, the coupler circuit 100 may be configured to output quadrature-phase signals (e.g., the first to fourth output signals O1(Z1) to O4(Z1) of FIG. 6) whose phases are sequentially shifted by 90 degrees, from differential input signals (e.g., the first input signal I1(Z0) and the second input signal I2(Z0) of FIG. 6) that are differentially related to each other.

Moreover, the coupler circuit 100 may be configured to convert the impedance of an input signal (e.g., the first input signal I1(Z0) in FIG. 2) and then may be configured to output output signals (e.g., the first output signal O1(Z1) and the second output signal O2(Z1) in FIG. 2) having a predetermined impedance (e.g., the target impedance Z1).

In other words, the coupler circuit 100 may be configured to perform an operation of generating complex signals from the input signal, and an impedance matching operation of allowing each of complex signals to have a target impedance.

Accordingly, compared to a case where a configuration for generating complex signals and a configuration for performing impedance matching are separately provided, the wireless communication device 800 (or the coupler circuit 100) according to an embodiment of the present disclosure may be implemented in a relatively small area.

That is, through the above-described configurations, the coupler circuit 100 according to an embodiment of the present disclosure may reduce the area required to implement the wireless communication device 800.

According to an embodiment, the RFIC 200 may further include the coupler circuit 100 connected between the local oscillator LO and the second mixer MX2.

Here, the coupler circuit 100 may be configured to split the signal received from the local oscillator LO into the I signal and the Q signal (e.g., the first output signal O1(Z1) and the second output signal O2(Z1) in FIG. 2) with different phases and may be configured to transmit I signal and Q signal to the second mixer MX2.

For another example, the RFIC 200 may further include the coupler circuit 100 connected between the first mixer MX1 and the amplifier 210.

Here, the coupler circuit 100 may be configured to split the signal received from the first mixer MX1 into I signal and Q signal (e.g., the first output signal O1(Z1) and the second output signal O2(Z1) in FIG. 2) with different phases and may transmit I signal and Q signal to the amplifier 210.

The power modulator 300 may generate a modulated output voltage, the level of which varies dynamically, based on the analog envelop signal A_ENV and the average power signal D_REF and may provide the modulated output voltage to the power amplifier PA as a power supply voltage.

In detail, the power modulator 300 may be provided with the average power signal D_REF and the analog envelop signal A_ENV from the communication processor 910. The power modulator 300 may be driven in the tracking mode corresponding to one of the ET mode and the APT mode based on the average power signal D_REF and the analog envelop signal A_ENV thus provided and may generate the dynamically variable output voltage. Also, the power modulator 300 may supply the generated output voltage to the power amplifier PA as the power supply voltage.

In an embodiment, when the power supply voltage of a fixed level is applied to the power amplifier PA, power efficiency of the power amplifier PA may decrease. Accordingly, to efficiently manage a power of the power amplifier PA, the power amplifier PA may modulate an input voltage (i.e., a power provided from a battery) based on at least one of the analog envelop signal A_ENV and the average power signal D_REF and may provide the modulated voltage to the power amplifier PA as the power supply voltage.

The RFFE 110 may separate the RF output signal RF_OUT provided from the power amplifier PA for each frequency band so as to be provided to the corresponding antenna 130. Also, the RFFE 110 may provide an external signal provided from the antenna 130 to the low-noise amplifier 220 included in the reception circuit RXC of the RFIC 200.

According to another embodiment, the RFFE 110 may include the power amplifier PA.

According to another embodiment, the RFFE 110 may include the coupler circuit 100 connected to the antenna 130. Here, the coupler circuit 100 may be understood as having substantially the same configuration as the coupler circuit 100 illustrated in FIG. 1A.

That is, referring to the above-described configurations, the coupler circuit 100 may be included in the RFIC 200 or the RFFE 110.

The antenna 130 may transmit the RF output signal RF_OUT to the outside or may provide the RF receive signal RF_R received from the outside to the RFIC 200. For example, the antenna 130 may include, but is not limited to, an array antenna.

In an embodiment, each of the communication processor 910, the power modulator 300, the RFIC 200, the power amplifier PA, and the RFFE 110 may be implemented with an integrated circuit, a chip, or a module. Also, the communication processor 910, the power modulator 300, the RFIC 200, the power amplifier PA, and the RFFE 110 may be together mounted on a printed circuit board (PCB). However, the technical idea of the present disclosure is not limited thereto. In some embodiments, at least a part of the communication processor 910, the power modulator 300, the RFIC 200, the power amplifier PA, and the RFFE 110 may be implemented with a single communication chip.

In addition, the wireless communication device 800 illustrated in FIG. 8 may be included in a wireless communication system that uses a cellular network such as 5G, LTE and may also be included in a wireless local area network (WLAN) system or any other wireless communication system. In an embodiment, a configuration of the wireless communication device 800 illustrated in FIG. 8 is, but is not limited to, an exemplary embodiment, and may be variously configured in compliance with a communication protocol or a communication scheme.

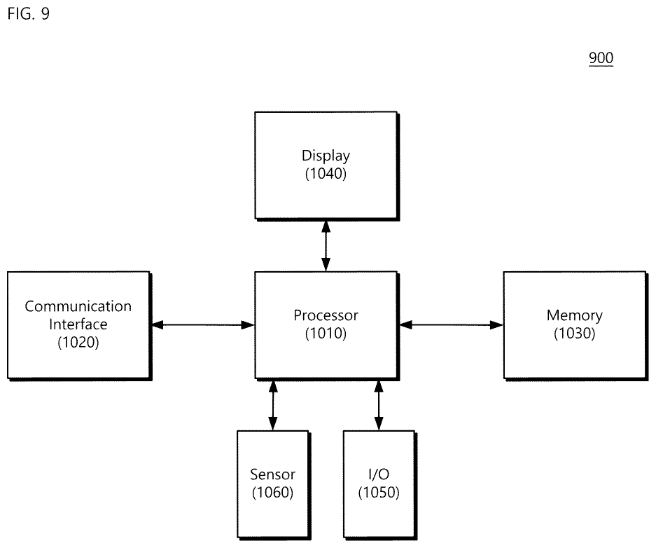

FIG. 9 is a block diagram illustrating an IoT device including an electronic device, according to an embodiment.

Referring to FIG. 9, an Internet of Things (IoT) may refer to a network between things that use wired and/or wireless communication. An IoT device 900 may include an accessible wired or/and wireless interface and may include devices that communicate with at least one or more other devices through the wired or/and wireless interface to transmit or receive data. The accessible interface that the IoT device 900 includes may include a modem communication interface that is accessible to a local area network (LAN), a wireless local area network (WLAN) such as a wireless fidelity (Wi-Fi), a wireless personal area network (WPAN) such as Bluetooth, a wireless universal serial bus (USB), a Zigbee, a near field communication (NFC), a radio-frequency identification (RFID), a power line communication (PLC), or mobile cellular networks such as 3rd generation (3G), long term evolution (LTE), 4th generation (4G), or 5th generation (5G). The Bluetooth interface may support Bluetooth low energy (BLE).

In detail, the IoT device 900 may include a communication interface 1020 for communicating with the outside. The communication interface 1020 may be, for example, a modem communication interface that is accessible to a wireless local area network such as an LAN, Bluetooth, Wi-Fi, or Zeebee, PLC, a mobile communication network, such as 3G, LTE, 4G, or 5G, etc.

The communication interface 1020 may include a transceiver and/or a receiver. Here, the communication interface 1020 illustrated in FIG. 9 may be understood to include at least some of the wireless communication device 10 illustrated in FIG. 1. For example, the communication interface 1020 may include the coupler circuit 100 connected to the antenna 130.

According to an embodiment, the coupler circuit 100 may be configured to output a plurality of complex signals having different phases from an input signal.

For example, the coupler circuit 100 may be configured to output an I signal and a Q signal (e.g., the first output signal O1(Z1) and the second output signal O2(Z1) of FIG. 2), which are orthogonal to each other, from a single-phase input signal (e.g., the first input signal I1(Z0) of FIG. 2).

For another example, the coupler circuit 100 may be configured to output quadrature-phase signals (e.g., the first to fourth output signals O1(Z1) to O4(Z1) of FIG. 6) whose phases are sequentially shifted by 90 degrees, from differential input signals (e.g., the first input signal I1(Z0) and the second input signal I2(Z0) of FIG. 6) that are differentially related to each other.

Moreover, the coupler circuit 100 may be configured to convert the impedance of an input signal (e.g., the first input signal I1(Z0) in FIG. 2) and then may be configured to output output signals (e.g., the first output signal O1(Z1) and the second output signal O2(Z1) in FIG. 2) having a predetermined impedance (e.g., the target impedance Z1).

In other words, the coupler circuit 100 may be configured to perform an operation of generating complex signals from the input signal, and an impedance matching operation of allowing each of complex signals to have a target impedance.

Accordingly, compared to a case where a configuration for generating complex signals and a configuration for performing impedance matching are separately provided, the IoT device 900 (or the coupler circuit 100) according to an embodiment of the present disclosure may be implemented in a relatively small area.

That is, through the above-described configurations, the coupler circuit 100 according to an embodiment of the present disclosure may reduce the area required to implement the IoT device 900.

The IoT device 900 may transmit and/or receive information from an access point or a gateway through the transceiver and/or the receiver. Also, the IoT device 900 may communicate with a user apparatus or any other IoT device to transmit and/or receive control information or data of the IoT device 900.

The IoT device 900 may include a processor 1010 that performs arithmetic operations.

For internal power supply, the IoT device 900 may further include an embedded battery or a power supply unit that is supplied with a power from the outside. Also, the IoT device 900 may include a display 1040 for displaying an internal state or data. The user may control the IoT device 900 through a user interface (UI) of the display 1040 in the IoT device 900. The IoT device 900 may transmit an internal state and/or data to the outside through the transceiver and may receive a control instruction and/or data to the outside through the receiver.

A memory 1030 may store a control instruction code controlling the IoT device 900, control data, or user data. The memory 1030 may include at least one of a volatile memory or a nonvolatile memory. The nonvolatile memory includes at least one of various memories such as a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), and a ferroelectric RAM (FRAM). The volatile memory may include at least one of various memories such as a static RAM (SRAM), a dynamic RAM (DRAM), and a synchronous DRAM (SDRAM).

The IoT device 900 may further include a storage device. The storage device may include at least one of nonvolatile media such as a solid state drive (SSD), an embedded multimedia card (eMMC), and universal flash storage (UFS). The storage device may store user information provided through an input/output unit (I/O) 1050 and pieces of sensing information collected through a sensor 1060.

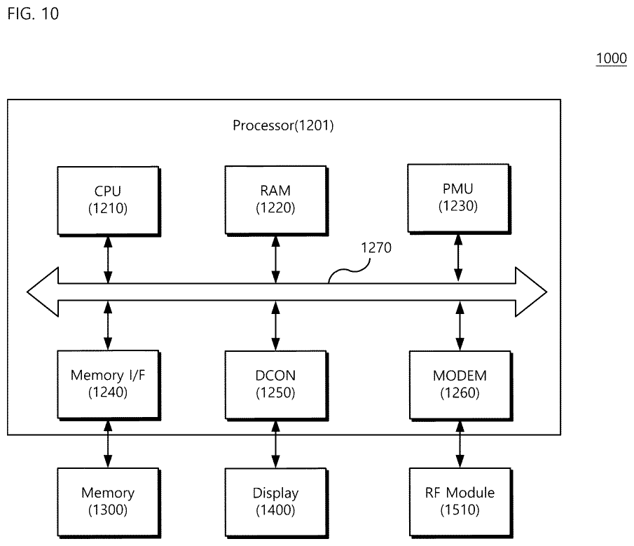

FIG. 10 is a block diagram showing a mobile terminal, to which an electronic device is applied, according to an embodiment.

Referring to FIG. 10, a mobile terminal 1000 may include a processor 1201, a memory 1300, a display 1400, and a radio frequency (RF) module 1510. In addition, the mobile terminal 1000 may further include various components such as a lens and an audio module.

The processor 1201 may be implemented with a system on chip (SoC) and may include a central processing unit (CPU) 1210, a RAM 1220, a power management unit (PMU) 1230, a memory interface (I/F) 1240, a display controller (DCON) 1250, a MODEM 1260, and a bus 1270. Besides, the processor 1201 may further include various intellectual properties (IPs). The processor 1201 may be integrated with a function of a MODEM chip therein, which is referred to as a “ModAP”, but is not limited thereto.

The CPU 1210 may control overall operations of the processor 1201 and the mobile terminal 1000. The CPU 1210 may control an operation of each component of the processor 1201. Also, the CPU 1210 may be implemented with a multi-core. The multi-core may be one computing component having two or more independent cores.

The RAM 1220 may temporarily store programs, data, or instructions. For example, the programs and/or data stored in the memory 1300 may be temporarily stored in the RAM 1220 under control of the CPU 1210 or depending on a booting code. The RAM 1220 may be implemented with a DRAM or an SRAM.

The PMU 1230 may manage power of each component of the processor 1201. The PMU 1230 may also determine an operating situation of each component of the processor 1201 and may control an operation thereof.

The memory interface 1240 may control overall operations of the memory 1300 and may control data exchange of the memory 1300 with each component of the processor 1201. Depending on a request of the CPU 1210, the memory interface 1240 may write data in the memory 1300 or may read data from the memory 1300.

The display controller 1250 may provide the display 1400 with image data to be displayed on the display 1400. The display 1400 may be implemented with a flat panel display, such as a liquid crystal display (LCD) or an organic light emitting diode (OLED) display, or a flexible display.

For wireless communication, the MODEM 1260 may modulate data to be transmitted so as to be appropriate for a wireless environment and may recover received data. The MODEM 1260 may perform digital communication with the RF module 1510.

The RF module 1510 may convert a high-frequency signal received through the antenna 130 into a low-frequency signal and may transmit the converted low-frequency signal to the MODEM 1260. Also, the RF module 1510 may convert a low-frequency signal received from the MODEM 1260 into a high-frequency signal and may transmit the converted high-frequency signal to the outside of the mobile terminal 1000 through the antenna. The RF module 1510 may amplify or filter a signal.

Here, the RF module 1510 may include at least part of the wireless communication device 10 illustrated in FIG. 1. For example, the RF module 1510 may include the coupler circuit 100 illustrated in FIGS. 1 and 2.

According to an embodiment, the coupler circuit 100 may be configured to output a plurality of complex signals having different phases from an input signal.

For example, the coupler circuit 100 may be configured to output I signal and Q signal (e.g., the first output signal O1(Z1) and the second output signal O2(Z1) of FIG. 2), which are orthogonal to each other, from a single-phase input signal (e.g., the first input signal I1(Z0) of FIG. 2).

For another example, the coupler circuit 100 may be configured to output quadrature-phase signals (e.g., the first to fourth output signals O1(Z1) to O4(Z1) of FIG. 6) whose phases are sequentially shifted by 90 degrees, from differential input signals (e.g., the first input signal I1(Z0) and the second input signal I2(Z0) of FIG. 6) that are differentially related to each other. Moreover, the coupler circuit 100 may be configured to convert the impedance of an input signal (e.g., the first input signal I1(Z0) in FIG. 2) and then may be configured to output output signals (e.g., the first output signal O1(Z1) and the second output signal O2(Z1) in FIG. 2) having a predetermined impedance (e.g., the target impedance Z1).

In other words, the coupler circuit 100 may be configured to perform an operation of generating complex signals from the input signal, and an impedance matching operation of allowing each of complex signals to have a target impedance.

Accordingly, compared to a case where a configuration for generating complex signals and a configuration for performing impedance matching are separately provided, the mobile terminal 1000 (or the coupler circuit 100) according to an embodiment of the present disclosure may be implemented in a relatively small area.

That is, through the above-described configurations, the coupler circuit 100 according to an embodiment of the present disclosure may reduce the area required to implement the mobile terminal 1000.

Referring to the above-described configurations, the coupler circuit 100 according to an embodiment of the present disclosure may include the transformers TF1 and TF2 implemented by combining at least some of inductors included in equivalent circuits of the plurality of transmission lines TL1, TL2, TL3, and TL4 with the ideal transformers ITF1 and ITF2.

The coupler circuit 100 may be configured to output the output signals O1(Z1) and O2(Z1) having different phases from the first input signal I1(Z0) by using the transformers TF1 and TF2 and a plurality of elements. Moreover, the coupler circuit 100 may be configured to perform impedance matching by using the transformers TF1 and TF2 and the plurality of elements such that each of the output signals O1(Z1) and O2(Z1) has the target impedance Z1.

That is, the coupler circuit 100 may be configured to perform an operation of generating the output signals O1(Z1) and O2(Z1) having different phases from the first input signal I1(Z0), and an impedance matching operation of allowing each of the output signals O1(Z1) and O2(Z1) to have the target impedance Z1.

Accordingly, compared to a case where a configuration for generating complex signals and a configuration for performing impedance matching are separately provided, the coupler circuit 100 according to an embodiment of the present disclosure may be implemented in a relatively small area.

That is, through the above-described configurations, the coupler circuit 100 according to an embodiment of the present disclosure may reduce the area required to implement the wireless communication device 10.

Embodiments in which a design is changed simply or which are easily changed may be included in the present disclosure as well as an embodiment described above. In addition, technologies that are easily changed and implemented by using the above embodiments may be included in the present disclosure. Accordingly, it will be apparent to those of ordinary skill in the art that various changes and modifications may be made to the above embodiments without departing from the spirit and scope of the present disclosure as set forth in the following claims.

A coupler circuit according to an embodiment of the present disclosure may reduce the area of a circuit required to implement a wireless communication device.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A coupler circuit comprising:
a first input terminal configured to receive an input signal having an input impedance;
a first output terminal configured to output a first output signal having a target impedance;
a first transformer connected between the first input terminal and the first output terminal, the first transformer comprising a first coil and a second coil, each of the first coil and the second coil comprising opposite ends;
a first node between the first input terminal and the first transformer;
a first inductor connected to the first node;
a first resistor connected to the first inductor;
a first capacitor connected in parallel to the opposite ends of the first coil of the first transformer;
a second capacitor connected in parallel to the opposite ends of the second coil of the first transformer;
a second output terminal configured to output a second output signal having the target impedance;
a second node between the first inductor and the first resistor;
a second transformer connected between the second output terminal and the second node, the second transformer comprising a third coil and a fourth coil, each of the third coil and the fourth coil comprising opposite ends;
a third capacitor connected in parallel to the opposite ends of the third coil of the second transformer;
a fourth capacitor connected in parallel to the opposite ends of the fourth coil of the second transformer; and
a second inductor connected between the first output terminal and the second output terminal.

2. The coupler circuit of claim 1, wherein the coupler circuit is configured to:
convert the input impedance of a first input signal applied through the first input terminal to the target impedance by using the first transformer, and output a first output signal having the target impedance through the first output terminal; and
convert an impedance of a signal applied to the second node by using the second transformer, and output a second output signal, which has the target impedance and is orthogonal to the first output signal, through the second output terminal.

3. The coupler circuit of claim 1, wherein the coupler circuit is configured to operate at an operating frequency,
wherein the first inductor has a first inductance equal to the input impedance divided by a product of two multiplied by Pi multiplied by the operating frequency, and
wherein the second inductor has a second inductance equal to the target impedance divided by the product of two multiplied by Pi multiplied by the operating frequency.

4. The coupler circuit of claim 1, wherein the first capacitor is further connected between the first node and ground,
wherein the second capacitor is further connected between the first output terminal and ground,
wherein the third capacitor is further connected between the second node and ground,
wherein the fourth capacitor is further connected between the second output terminal and ground, and
wherein one end of the first resistor is connected to ground.

5. The coupler circuit of claim 2, further comprising:
a second input terminal configured to receive a second input signal that is differential with the first input signal;
a third output terminal configured to output a third output signal that is differential with the first output signal; and
a fourth output terminal configured to output a fourth output signal that is differential with the second output signal,
wherein the first capacitor is further connected between the first input terminal and the second input terminal,
wherein the second capacitor is connected between the first output terminal and the third output terminal,
wherein the third capacitor is connected to the second node, and
wherein the fourth capacitor is connected between the second output terminal and the fourth output terminal.

6. The coupler circuit of claim 5, wherein the coupler circuit is configured to output each of the third output signal and the fourth output signal having the target impedance, and
wherein the coupler is configured to output the third output signal and the fourth output signal orthogonal to each other.

7. The coupler circuit of claim 5, further comprising:
a third node between the second output terminal and the first transformer;
a fourth node between the first resistor and the second transformer;
a third inductor connected between the third node and the fourth node; and
a fourth inductor connected between the third output terminal and the fourth output terminal.

8. The coupler circuit of claim 7, wherein the first inductor and the third inductor are adjacent to each other and are inductively coupled to each other, and
wherein the first inductor and the third inductor are configured to flow currents in directions opposite to each other.

9. The coupler circuit of claim 1, wherein the first capacitor and the third capacitor have a same capacitance, and
wherein the second capacitor and the fourth capacitor have a same capacitance.

10. The coupler circuit of claim 3, further comprising:
an input transistor connected to the first input terminal,
wherein the first capacitor has a capacitance equal to a difference between an input capacitance of the input transistor and a first capacitance C1 given by the following equation:
$$C1 = √ ( ( 1 + √ 2 ) / ( 2 π f \times Z 0 ) )$$
where Z0 is the input impedance and f is the operating frequency.

11. A wireless communication device comprising:
an antenna configured to transmit and receive an RF signal having a predetermined frequency;
a radio frequency front end (RFFE) including a coupler circuit connected to the antenna, the coupler circuit including at least two or more transformers; and
a radio frequency integrated circuit (RFIC) connected to the RFFE and configured to control a frequency of the RF signal,
wherein the coupler circuit is configured to receive a first input signal, having an input impedance, from the RFIC and output a first output signal and a second output signal, each having a target impedance and being orthogonal to each other, from the first input signal.

12. The wireless communication device of claim 11, wherein the coupler circuit comprises:
a first input terminal connected to the RFIC;
a first output terminal;
a first transformer connected between the first input terminal and the first output terminal, the first transformer comprising a first coil and a second coil, each of the first coil and the second coil comprising opposite ends;
a first node between the first input terminal and the first transformer;
a first inductor connected to the first node;
a first resistor connected to the first inductor;
a first capacitor connected in parallel to the opposite ends of the first coil of the first transformer;
a second capacitor connected in parallel to the opposite ends of the second coil of the first transformer;
a second output terminal;
a second node between the first inductor and the first resistor;
a second transformer connected between the second output terminal and the second node, the second transformer comprising a third coil and a fourth coil, each of the third coil and the fourth coil comprising opposite ends;
a third capacitor connected in parallel to the opposite ends of the third coil of the second transformer;
a fourth capacitor connected in parallel to the opposite ends of the fourth coil of the second transformer; and
a second inductor connected between the first output terminal and the second output terminal.

13. The wireless communication device of claim 12, wherein the coupler circuit is configured to:
convert an impedance of the first input signal by using the first transformer, and output the first output signal having the target impedance through the first output terminal; and
convert an impedance of a signal applied to the second node by using the second transformer, and output the second output signal having the target impedance through the second output terminal.

14. The wireless communication device of claim 13, wherein the first capacitor is further connected between the first node and ground, wherein the second capacitor is further connected between the first output terminal and ground,
wherein the third capacitor is further connected between the second node and ground,
wherein the fourth capacitor is further connected between the second output terminal and ground, and
wherein one end of the first resistor is connected to ground.

15. The wireless communication device of claim 13, further comprising:
a second input terminal configured to receive a second input signal that is differential with the first input signal;
a third output terminal configured to output a third output signal that is differential with the first output signal; and
a fourth output terminal configured to output a fourth output signal that is differential with the second output signal,
wherein the first capacitor is further connected between the first input terminal and the second input terminal,
wherein the second capacitor is further connected between the first output terminal and the third output terminal,
wherein the third capacitor is further connected to the second node, and
wherein the fourth capacitor is further connected between the second output terminal and the fourth output terminal.

16. The wireless communication device of claim 15, further comprising:
a third node between the second input terminal and the first transformer;
a fourth node between the first resistor and the second transformer;
a third inductor connected between the third node and the fourth node; and
a fourth inductor connected between the third output terminal and the fourth output terminal,
wherein the first inductor and the third inductor are adjacent to each other and are inductively coupled to each other, and
wherein the second inductor and the fourth inductor are adjacent to each other and are inductively coupled to each other.

17. The wireless communication device of claim 12, further comprising:
a first output transistor connected to the first output terminal,
wherein the second capacitor has a capacitance equal to a difference between a parasitic capacitance of the first output transistor and a second capacitance C2 given by the following equation:
$$C 2 = 1 / ( 2 π f \times Z 1 ) + Z 0 / Z 1 ( √ 2 / 2 π f + C p )$$
where Cp is a first capacitance of the first capacitor, Z0 is the input impedance, Z1 is the target impedance, and f is an operating frequency of the coupler circuit.

18. A coupler circuit comprising:
a first input terminal configured to receive an input signal having an input impedance;
a first output terminal configured to output a first output signal having a target impedance;
a first reference node, wherein the input signal is defined with respect to the first reference node;
a second reference node, wherein the first output signal is defined with respect to the second reference node;
a first transformer connected between the first input terminal and the first output terminal, the first transformer comprising a first coil connected between the first input terminal and the first reference node and a second coil inductively coupled to the first coil and connected between the first output terminal and the second reference node;
a first node between the first input terminal and the first coil of the first transformer;
a first inductor connected to the first node;
a first resistor connected to the first inductor;
a second output terminal configured to output a second output signal having the target impedance;
a second node between the first inductor and the first resistor;
a third reference node;
a fourth reference node, wherein the second output signal is defined with respect to the third reference node;
a second transformer connected between the second output terminal and the second node, the second transformer comprising a third coil connected between the second node and the third reference node and a fourth coil connected between the second output terminal and the fourth reference node; and
a second inductor connected between the first output terminal and the second output terminal.

19. The coupler circuit of claim 18, wherein the coupler circuit is configured to:
convert an impedance of a first input signal applied to the first node by using the first transformer, and output the first output signal having the target impedance through the first output terminal; and
convert an impedance of a signal applied to the second node by using the second transformer, and output the second output signal, which has the target impedance and is orthogonal to the first output signal, through the second output terminal.

20. The coupler circuit of claim 18, wherein each of the first reference node, the second reference node, the third reference node, and the fourth reference node is grounded.
